(19) United States
(12) Patent Application Publication
(10) Pub. No.: US 2025/0081744 A1
(43) Pub. Date: Mar. 6, 2025

(54) DISPLAY DEVICE

(71) Applicant: Samsung Display Co., LTD., Yongin-si (KR)

(72) Inventors: Jae Heung HA, Yongin-si (KR); Chang Yeong SONG, Yongin-si (KR); Jong Woo KIM, Yongin-si (KR)

(73) Assignee: Samsung Display Co., LTD., Yongin-si (KR)

(21) Appl. No.: 18/658,219

(22) Filed: May 8, 2024

(30) Foreign Application Priority Data
Aug. 29, 2023 (KR) 10-2023-0113977

(51) Int. Cl. H10K 59/122; H10K 59/80; H10K 102/00

(52) U.S. Cl. CPC H10K 59/122; H10K 59/8722; H10K 2102/351

(57) ABSTRACT

A display device includes a first substrate, a transistor on the first substrate, a pixel electrode disposed on the transistor and connected to the transistor, a pixel defining layer on the pixel electrode, a spacer on the pixel defining layer, and a second substrate on the spacer. The spacer includes a first spacer disposed at a center of the first substrate and a second spacer disposed at an edge of the first substrate in a plan view, and the second spacer has a width that gradually increases in a direction from the first substrate toward the second substrate.

### CROSS-REFERENCE TO RELATED APPLICATION(S)

This application claims priority to and benefits of Korean Patent Application No. 10-2023-0113977 under 35 U.S.C. 119, filed on Aug. 29, 2023, in the Korean Intellectual Property Office (KIPO), the entire contents of which are incorporated herein by reference.

### BACKGROUND

### 1. Technical Field

The disclosure relates to a display device capable of preventing a darkening of a pixel.

### 2. Description of the Related Art

Organic light emitting display devices have self-light-emitting properties and, unlike liquid crystal display devices, do not require a separate light source, thereby reducing thickness and weight. Organic light emitting display devices are attracting attention as next-generation display devices for portable electronic devices due to high-quality characteristics such as low power consumption, high brightness, and high response speed.

### SUMMARY

Aspects of the disclosure provide a display device capable of preventing a darkening of a pixel.

According to an embodiment of the disclosure, a display device may include a first substrate, a transistor on the first substrate, a pixel electrode disposed on the transistor and connected to the transistor, a pixel defining layer on the pixel electrode, a spacer on the pixel defining layer, and a second substrate on the spacer. The spacer may include a first spacer disposed at a center of the first substrate and a second spacer disposed at an edge of the first substrate in a plan view, and the second spacer may have a width that gradually increases in a direction from the first substrate toward the second substrate.

In an embodiment, the first spacer may have a width that gradually decreases in the direction.

In an embodiment, an interior angle of the second spacer may be an obtuse angle.

In an embodiment, an interior angle of the first spacer may be an acute angle.

In an embodiment, the display device may further include a filler between the first substrate and the second substrate.

In an embodiment, the second spacer may have a groove.

In an embodiment, the second spacer and the filler may be in contact with each other through the groove of the second spacer.

In an embodiment, the display device may further include a sealant disposed between the edge of the first substrate and an edge of the second substrate and surround the filler and the spacer.

In an embodiment, the spacer may be formed integrally with the pixel defining layer.

In an embodiment, each of the first spacer and the second spacer may be formed integrally with the pixel defining layer.

In an embodiment, the filler may be formed of a silicon-based material.

According to an embodiment of the disclosure, a display device may include a first substrate, a transistor on the first substrate, a pixel electrode disposed on the transistor and connected to the transistor, a pixel defining layer on the pixel electrode, and a first spacer disposed on the pixel defining layer at an edge of the first substrate in a plan view. The first spacer may have a width that gradually increases in a direction from the first substrate toward a second substrate.

In an embodiment, an interior angle of the first spacer may be an obtuse angle.

In an embodiment, the display device may further include a second spacer disposed on the pixel defining layer at a center of the first substrate in a plan view. The second spacer may have a width that gradually decreases in the direction.

In an embodiment, an interior angle of the second spacer may be an acute angle.

In an embodiment, the display device may further include a filler between the first substrate and the second substrate.

In an embodiment, the first spacer may have a groove.

In an embodiment, the first spacer and the filler may be in contact with each other through the groove of the first spacer.

In an embodiment, the display device may further include a sealant disposed between the edge of the first substrate and an edge of the second substrate and surround the filler, the first spacer, and the second spacer.

In an embodiment, each of the first spacer and the second spacer may be formed integrally with the pixel defining layer.

In the display device according to the disclosure, a darkening of a pixel may be prevented.

### BRIEF DESCRIPTION OF THE DRAWINGS

The above and other aspects and features of the disclosure will become more apparent by describing in detail embodiments thereof with reference to the attached drawings, in which:

FIG. 1 is a plan view of a display device according to an embodiment;

FIG. 2 is a schematic diagram separately illustrating spacers in FIG. 1;

FIG. 3 is a schematic cross-sectional view taken along line I-I′ of FIG. 1;

FIG. 4 is a schematic plan view of a unit pixel of FIG. 1;

FIG. 5 is a schematic cross-sectional view taken along line II-II′ of FIG. 4;

FIG. 6 is a schematic diagram for explaining a moving path of a filler due to a damage of a first spacer; and

FIG. 7 is a schematic diagram for explaining a moving path of a filler due to a damage of a second spacer.

### DETAILED DESCRIPTION OF THE EMBODIMENTS

The embodiments will now be described more fully hereinafter with reference to the accompanying drawings, in which embodiments of the disclosure are shown. The disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

In the specification and the claims, the phrase “at least one of” is intended to include the meaning of “at least one selected from the group of” for the purpose of its meaning and interpretation. For example, “at least one of A and B” may be understood to mean “A, B, or A and B.”

Features of various embodiments of the present disclosure may be combined partially or totally. As will be clearly appreciated by those skilled in the art, technically various interactions and operations are possible. Various embodiments can be practiced individually or in combination.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments will be described in detail with reference to the accompanying drawings.

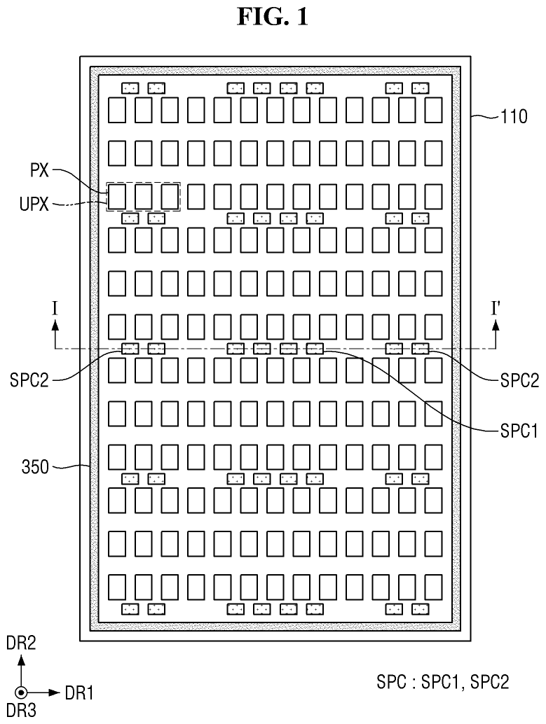

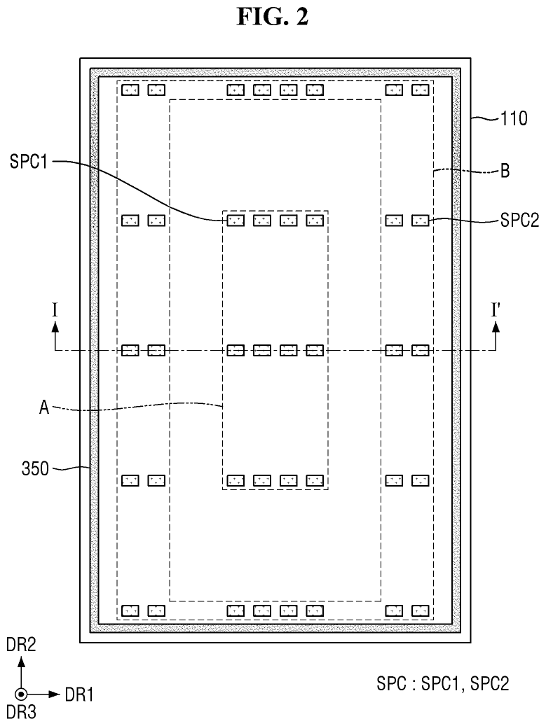

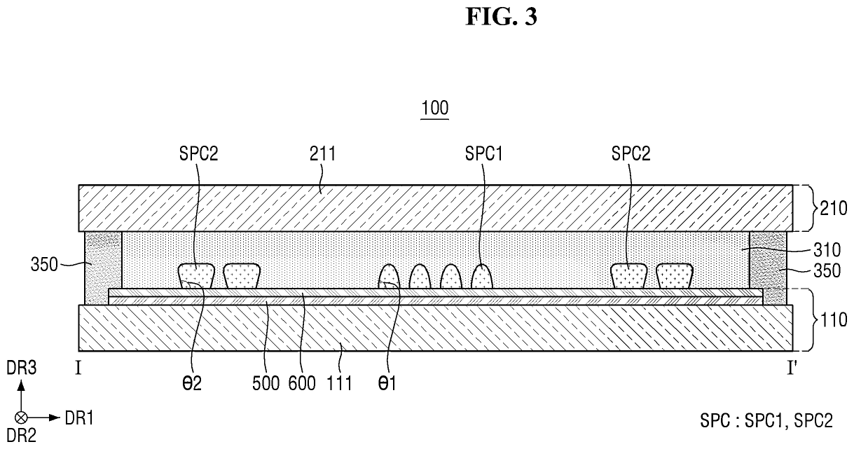

FIG. 1 is a plan view of a display device 100 according to an embodiment, FIG. 2 is a schematic diagram separately illustrating spacers in FIG. 1, and FIG. 3 is a schematic cross-sectional view taken along line I-I′ of FIG. 1.

As illustrated in FIGS. 1 to 3, the display device 100 may include a display substrate 110, an encapsulation substrate 210, a sealant 350, a filler 310 and multiple spacers SPC.

The display substrate 110 may include a first substrate 111, a driving circuit layer 500 disposed on the first substrate 111, and a light emitting element layer 600 disposed on the driving circuit layer 500. The display substrate 110 may include multiple pixels arranged in a display area of the display substrate 110. A pixel may include multiple transistors and a light emitting element connected to at least one of the transistors. The transistors may be disposed in the driving circuit layer 500 described above, and a light emitting element may be disposed in the light emitting element layer described above. Three adjacent pixels PX may provide light of different colors, and the three pixels may form one unit pixel UPX.

The encapsulation substrate 210 may be disposed opposite to the display substrate 110 and cover the light emitting element layer 600 and the driving circuit layer 500 of the display substrate 110. The encapsulation substrate 210 may include a second substrate 211.

The sealant 350 may be disposed along the edges of the display substrate 110 and the encapsulation substrate 210 to bond and scal the display substrate 110 and the encapsulation substrate 210. For example, the sealant 350 may be disposed between the edge of the first substrate 111 and the edge of the second substrate 211. In a plan view, the sealant 350 may have a closed curve shape surrounding the pixels, the spacers SPC, and a filler 310 to be described below.

The filler 310 may be disposed in a space between the display substrate 110 and the encapsulation substrate 210. The filler 310 may fill the empty space between the display substrate 110 and the encapsulation substrate 210 to improve the mechanical strength of the display device 100. For example, the filler 310 may improve the durability of the display device 100 against external impact by filling the empty space inside the display device 100. In an embodiment, the filler 310 may be formed of a silicon-based material.

The spacers SPC may be disposed on at least one of the display substrate 110 and the encapsulation substrate 210 to maintain a gap between the display substrate 110 and the encapsulation substrate 210.

The spacers SPC may include multiple first spacers SPC1 disposed at the center of the first substrate 111, and multiple second spacers SPC2 disposed at the edge of the first substrate 111. For example, as illustrated in FIG. 2, the spacers SPC may include the first spacers SPC1 disposed in area A corresponding to the center of the first substrate 111, and the second spacers SPC2 disposed in area B corresponding to the edge of first substrate 111. The second spacers SPC2 may be disposed closer to the sealant 350 than the first spacers SPC1. In other words, the distance between the second spacer SPC2 and the sealant 350 may be smaller than the distance between the first spacer SPC1 and the sealant 350.

The first spacer SPC1 and the second spacer SPC2 may have different shapes. For example, the first spacer SPC1 may have a width that gradually decreases in the direction from the first substrate 111 to the second substrate 211 (e.g., a third direction DR3). The second spacer SPC2 may have a width that gradually increases in the third direction DR3 described above. For example, the second spacer SPC2 may have an inverse taper shape or an overhang shape in a cross-sectional view. Here, the width of each of the spacers SPC1 and SPC2 may be, for example, the size in a first direction DR1 or a second direction DR2.

The interior angle θ1 of the first spacer SPC1 may be an acute angle. For example, the interior angle θ1 of the first spacer SPC1 may be less than 90 degrees. The interior angle of the first spacer SPC1 may be, for example, an angle formed by a first virtual surface parallel to the first direction DR1 (or the second direction DR2) and a second virtual surface parallel to the side surface of the first spacer SPC1. Similarly, the interior angle θ2 of the second spacer SPC2 may be an angle formed by the first virtual surface and the second virtual surface described above.

The first spacer SPC1 and the second spacer SPC2 may serve to support a mask (e.g., a fine metal mask (FMM)) used during the deposition process of a light emitting layer. In case that the mask is disposed on the display substrate 110, the mask may sag toward the display substrate 110 due to its own weight. Damage may occur to the spacer supporting the mask due to the sagging of the mask, and the filler may penetrate into an emission area of the pixel through the damaged portion of the spacer, which may cause the problem of darkening the pixel. The sagging of the mask may occur at the edge of the display substrate 110, and thus damage may occur in the second spacer SPC2 disposed at the edge of the display substrate 110. However, since the second spacer SPC2 according to an embodiment has an inverse taper shape (or an overhang shape), a hole transporting layer and an electron transporting layer, which will be described below, may be disconnected for each pixel by the second spacer SPC2. Therefore, even in case that damage occurs in the second spacer SPC2, the filler 310 may not penetrate into the emission area of the pixel. Accordingly, even in case that damage occurs in the second spacer SPC2, a darkening of the pixel can be prevented.

A manufacturing method of the display device 100 according to an embodiment will be described below.

First, the sealant 350 may be applied along the edge on the display substrate 110 or the encapsulation substrate 210, and a filler 310 may be loaded on the display substrate 110 or the encapsulation substrate 210 where the sealant 350 is applied. The filler 310 may be dropped inside the sealant 350. For example, the filler 310 may be dropped from the center of the display substrate 110 or the encapsulation substrate 210.

The display substrate 110 and the encapsulation substrate 210 may be bonded to each other through a vacuum bonding method with the sealant 350 and the filler 310 interposed between the display substrate 110 and the encapsulation substrate 210. The sealant 350 may be cured while the display substrate 110 and the encapsulation substrate 210 are bonded together.

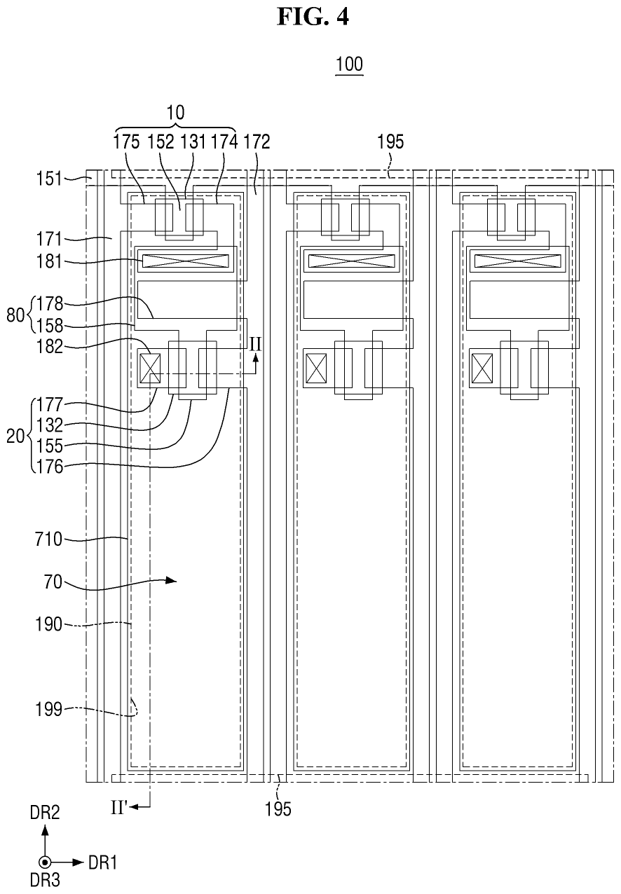

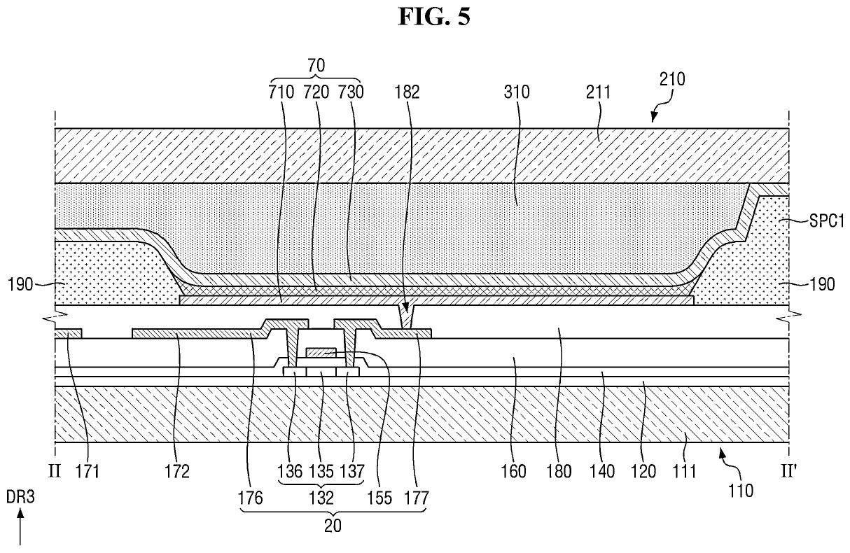

Hereinafter, with reference to FIGS. 4 and 5, pixels of a light emitting display device 100 according to an embodiment will be described below.

FIG. 4 is a schematic plan view of a unit pixel of FIG. 1, and FIG. 5 is a schematic cross-sectional view taken along line II-II′ of FIG. 4.

The display substrate 110 may include a switching transistor 10, a driving transistor 20, a storage element 80, and a light emitting element 70, respectively formed for each pixel. The light emitting element 70 may be, for example, an organic light emitting diode (OLED). The display substrate 110 may further include a gate line 151 extending in a direction, a data line 171 that insulates and intersects the gate line 151, and a common power line 172. One pixel may be defined by the gate line 151, the data line 171, and the common power line 172, but the disclosure is not necessarily limited thereto.

The light emitting element 70 may include a pixel electrode 710, a light emitting layer 720 disposed on the pixel electrode 710, and a common electrode 730 disposed on the light emitting layer 720. The pixel electrode 710 may correspond to a positive (+) electrode, which is a hole injection electrode, and the common electrode 730 may correspond to a negative (−) electrode, which is an electron injection electrode. However, the disclosure is not necessarily limited thereto, and depending on the driving method of the display device 100, the pixel electrode 710 may correspond to a negative electrode, and the common electrode 730 may correspond to a positive electrode.

Holes and electrons may be injected into the organic light emitting layer 720 from the pixel electrode 710 and the common electrode 730, respectively. Light emission may occur in case that exciton, which is a combination of injected holes and electrons, falls from the excited state to the ground state.

In the display device 100 according to an embodiment, the light emitting element 70 may emit light from the light emitting layer 720 in the opposite direction of the pixel electrode 710 direction, for example, the common electrode 730 direction and display an image. In other words, the display device 100 according to an embodiment may be a top-light-emitting display device 100.

The storage element 80 may include a first capacitor plate 158 and a second capacitor plate 178, and a gate insulating layer 140 may be interposed between the first capacitor plate 158 and the second capacitor plate 178. The gate insulating layer 140 may function as a dielectric of the storage element 80. In the storage element 80, a storage amount of storage element 80 may be determined by the voltage between both storage plates 158 and 178 and the stored charge.

The switching transistor 10 may include a switching semiconductor layer 131, a switching gate electrode 152, a switching source electrode 173, and a switching drain electrode 174, and the driving transistor 20 may include a driving semiconductor layer 132, a driving gate electrode 155, a driving source electrode 176, and a driving drain electrode 177.

The switching transistor 10 may function as a switching element that selects a pixel to emit light. The switching gate electrode 152 may be connected to the gate line 151. The switching source electrode 173 may be connected to the data line 171. The switching drain electrode 174 may be spaced apart from the switching source electrode 173 and connected to the first capacitor plate 158.

The driving transistor 20 may apply driving power to the pixel electrode 710 to cause the light emitting layer 720 of the light emitting element 70 in the selected pixel to emit light. The driving gate electrode 155 may be connected to the first capacitor plate 158. The driving source electrode 176 and the second capacitor plate 178 may each be connected to the common power line 172. The driving drain electrode 177 may be connected to the pixel electrode 710 of the light emitting element 70 through a contact hole 182.

With the structure, the switching transistor 10 may be turned on by the gate voltage applied to the gate line 151, and the data voltage from the data line 171 may be transmitted to the driving transistor 20 by the turned-on switching transistor 10. A difference voltage corresponding to the difference between the common voltage applied to the driving transistor 20 from the common power line 172 and the data voltage transmitted from the switching transistor 10 may be stored in the storage element 80, and a current corresponding to the voltage stored in the storage element 80 may flow to the light emitting element 70 through the driving transistor 20, allowing the light emitting element 70 to emit light.

Hereinafter, a structure of the display device 100 according to an embodiment will be described in detail in the stacking order. Hereinafter, the structure of the transistor will be described focusing on the driving transistor 20. Also, only the differences between the switching transistor 10 and the driving transistor 20 will be briefly described.

The first substrate 111 of the display substrate 110 may be an insulating substrate made of glass, quartz, ceramic, plastic, or the like, but the disclosure is not limited thereto. For example, the first substrate 111 may be a metallic substrate made of stainless steel or the like.

A buffer layer 120 may be disposed on the first substrate 111. The buffer layer 120 may serve to prevent penetration of impurity elements and planarize the surface, and may be formed of a material capable of performing this role. For example, the buffer layer 120 may be formed of one of a silicon nitride (SiNₓ) layer, a silicon oxide (SiOₓ) layer, or a silicon oxynitride (SiOₓN_{y}) layer. However, the disclosure is not limited thereto, and the buffer layer 120 may be omitted depending on the type and process conditions of the first substrate 111.

The driving semiconductor layer 132 may be disposed on the buffer layer 120. The driving semiconductor layer 132 may be formed of a polycrystalline silicon layer. The driving semiconductor layer 132 may include a channel region 135 that is not doped with impurities, and a source region 136 and a drain region 137 formed by p+ doping on sides of the channel region 135. The ionic material to be doped may be a P-type impurity such as boron (B), and for example, B2H6 may be used. The impurities may vary depending on the type of a thin film transistor.

In an embodiment, a PMOS structure thin film transistor using P-type impurities may be used as the driving transistor 20, but the disclosure is not limited thereto. For example, a thin film transistor with an NMOS structure or a CMOS structure may be used as the driving transistor 20.

The driving transistor 20 illustrated in FIG. 5 may be a polycrystalline thin film transistor including a polycrystalline silicon layer, and the switching transistor 10 not illustrated in FIG. 5 may be a polycrystalline thin film transistor or an amorphous thin film transistor including an amorphous silicon layer.

The gate insulating layer 140 formed of silicon nitride (SiNₓ) or silicon oxide (SiOₓ) may be disposed on the driving semiconductor layer 132. A gate line including a driving gate electrode 155 may be formed on the gate insulating layer 140. The gate line may further include a gate line 151, a first capacitor plate 158, and other line. The driving gate electrode 155 may overlap at least a portion of the driving semiconductor layer 132 in a plan view, specifically the channel region 135.

An interlayer insulating layer 160 covering the driving gate electrode 155 may be disposed on the gate insulating layer 140. The gate insulating layer 140 and the interlayer insulating layer 160 may have a contact hole that exposes the source region 136 and drain region 137 of the driving semiconductor layer 132.

Like the gate insulating layer 140, the interlayer insulating layer 160 may be formed of silicon nitride (SiNₓ) or silicon oxide (SiOₓ).

A data line including a driving source electrode 176 and a driving drain electrode 177 may be formed on the interlayer insulating layer 160. The data line may further include a data line 171, a common power line 172, a second capacitor plate 178, and other lines. The driving source electrode 176 and the driving drain electrode 177 may be connected to the source region 136 and drain region 137 of the driving semiconductor layer 132, respectively, through contact holes of the interlayer insulating layer 160 and the gate insulating layer 140.

A planarization layer 180 covering the data lines 172, 176, 177, and 178 may be disposed on the interlayer insulating layer 160. The planarization layer 180 may serve to remove steps and planarize the steps to increase the luminous efficiency of the light emitting element 70 to be formed thereon.

Further, the planarization layer 180 may have a contact hole 182 that exposes a portion of the drain electrode 177.

The planarization layer 180 may be formed of at least one of an acrylic resin, an epoxy resin, a phenolic resin, a polyamides resin, a polyimides resin, an unsaturated polyester resin, a polyphenylenethers resin, a polyphenylenesulfides resin, and benzocyclobutene (BCB).

In an embodiment, one of planarization layer 180 or the interlayer insulating layer 160 may be omitted.

The pixel electrode 710 of the light emitting element 70 may be disposed on the planarization layer 180. For example, the display device 100 may include multiple pixel electrodes 710 respectively disposed for each of the pixels, and the pixel electrodes 710 may be arranged to be spaced apart from each other. The pixel electrode 710 may be connected to the drain electrode 177 through the contact hole 182 of the planarization layer 180.

A pixel defining layer 190 having multiple openings 199 exposing each of the pixel electrodes 710 may be disposed on the planarization layer 180. For example, the opening 199 of the pixel defining layer 190 may be formed for each pixel. Also, the pixel electrode 710 may be disposed to correspond to the opening 199 of the pixel defining layer 190. However, the arrangement of the pixel electrode 710 is not necessarily limited thereto, and a portion of the pixel electrode 710 may be located below the pixel defining layer 190 so as to overlap the pixel defining layer 190 in a plan view. The pixel defining layer 190 may correspond to a non-emission area of the pixel, and the opening 199 of the pixel defining layer 190 may correspond to an emission area of the pixel.

The spacers SPC1 and SPC2 may be disposed on the pixel defining layer 190. For example, the spacers SPC1 and SPC2 may be placed in the non-emission area of the pixel. The spacers SPC1 and SPC2 may maintain a gap between the display substrate 110 and the encapsulation substrate 210 to prevent contact with each other.

The pixel defining layer 190 and the spacers SPC1 and SPC2 may be formed of a resin such as a polyacrylates resin or polyimide, or a silica-based inorganic material. The pixel defining layer 190 and the spacers SPC1 and SPC2 may be formed integrally through a photo process or photo etching process. For example, the pixel defining layer 190 and the spacers SPC1 and SPC2 may be formed together through a halftone exposure process. However, the disclosure is not limited thereto, and for example, the pixel defining layer 190 and the spacers SPC1 and SPC2 may be formed sequentially or separately, and may be formed using different materials.

The light emitting layer 720 may be disposed on the pixel electrode 710, and the common electrode 730 may be disposed on the light emitting layer 720.

The light emitting layer 720 may be disposed between the pixel electrode 710 and the common electrode 730 in the opening 199 of the pixel defining layer 190 and provide light. The common electrode 730 may be disposed on the light emitting layer 720, the pixel defining layer 190, and the spacers SPC1 and SPC2.

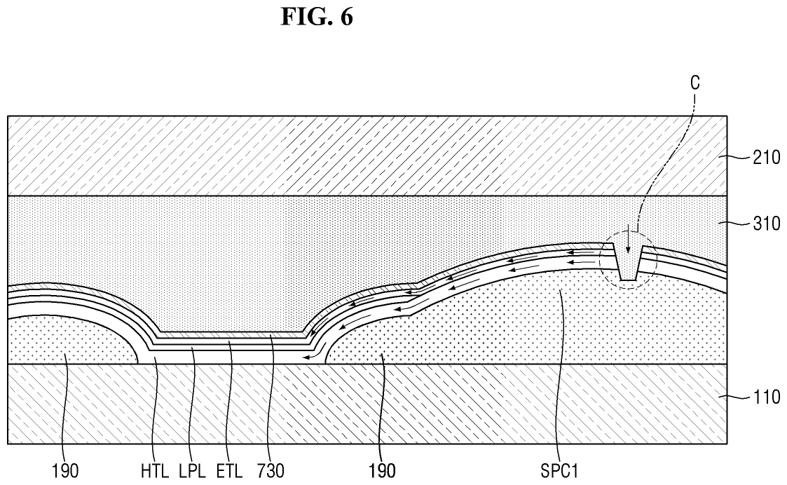

The light emitting layer 720 may be made of a low-molecular organic material or a high-molecular organic material. The light emitting layer 720 may be formed of a multiple layer including one or more of a light-providing layer LPL (FIG. 6), a hole injection layer, a hole transporting layer HTL (FIG. 6), an electron transporting layer ETL, and an electron injection layer. In case that all of the above are included, the hole injection layer may be disposed on the pixel electrode 710, which is the positive electrode, and the hole transporting layer, the light-providing layer, the electron transporting layer, and the electron injection layer may be sequentially stacked on a pixel electrode 710.

In FIG. 5, the light emitting layer 720 may be disposed only in the opening 199 of the pixel defining layer 190, but the disclosure is not limited thereto. For example, the light emitting layer 720 may be formed on the pixel electrode 710 in the opening 199 of the pixel defining layer 190 and may also be disposed between the pixel defining layer 190 and the common electrode 730. For example, in case that the light emitting layer includes multiple layers such as the hole injection layer, the hole transporting layer HTL, the electron transporting layer ETL, and the electron injection layer together with the light-providing layer LPL (see FIG. 6), the rest of the layers except the light-providing layer LPL (e.g., the hole injection layer, the hole transporting layer HTL, the electron transporting layer ETL, and the electron injection layer) may be formed not only on the pixel electrode 710 but also on the pixel defining layer 190 like the common electrode 730 by using an open mask during the manufacturing process. In other words, one or more layers of the layers belonging to the light emitting layer 720 may be disposed between the pixel defining layer 190 and the common electrode 730.

The pixel electrode 710 and the common electrode 730 may each be formed of a transparent conductive material or a transflective or reflective conductive material. Depending on the type of material forming the pixel electrode 710 and the common electrode 730, the display device 100 may be one of a top-light-emitting type, a bottom-light-emitting type, or a double-sided light-emitting type.

The display device 100 according to an embodiment may be a top-light-emitting type display device 100. For example, the light emitting element 70 may display an image by emitting light in the direction to the encapsulation substrate 210 (e.g., the third direction DR3).

Transparent conductive materials such as indium tin oxide (ITO), indium zinc oxide (IZO), zinc oxide (ZnO), or indium oxide (In₂O₃) may be used. Reflective and transflective materials such as lithium (Li), calcium (Ca), lithium fluoride/calcium (LiF/Ca), lithium fluoride/aluminum (LiF/Al), aluminum (Al), silver (Ag), magnesium (Mg), or gold (Au) may be used.

An encapsulation substrate 210 may be disposed on the common electrode 730. For example, the encapsulation substrate 210 may face the display substrate 110 and cover the transistors 10 and 20, the storage element 80, and the organic light emitting element 70 to seal them from the outside.

The encapsulation substrate 210 may include a second substrate 211. The display substrate 110 and the encapsulation substrate 210 may be bonded to each other by the sealant 350 disposed along the edges of the display substrate 110 and the encapsulation substrate 210, and thus the display device 100 may be sealed.

FIG. 6 is a schematic diagram for explaining a moving path of a filler due to a damage of a first spacer SPC1.

Damage may occur in the first spacer SPC1 supporting the mask due to sagging of the mask. For example, as illustrated in FIG. 6, damage may occur in an area C, causing damage to the common electrode 730, the electron transporting layer ETL, the hole transporting layer HTL, and the first spacer SPC1. The filler 310 may penetrate into the emission area of the pixel through the damaged portion, which may cause the problem of darkening of the pixel.

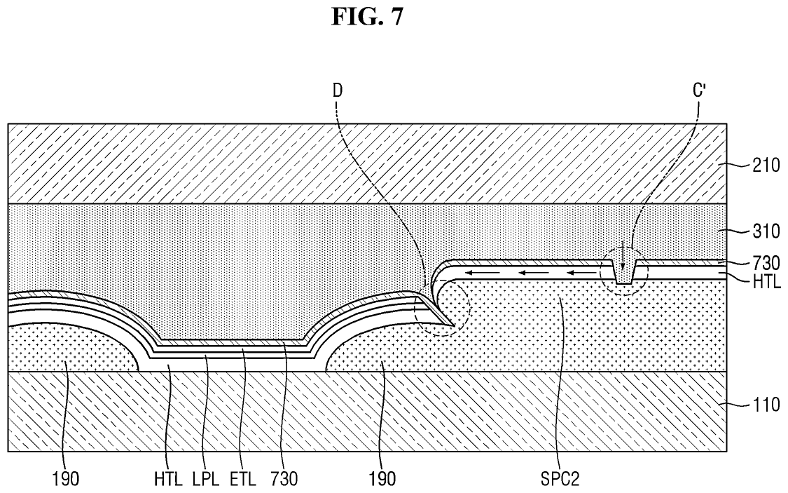

FIG. 7 is a schematic diagram for explaining a moving path of a filler 310 due to a damage of a second spacer SPC2.

Damage may occur in the second spacer SPC2 supporting the mask due to sagging of the mask. For example, as illustrated in FIG. 7, a damage may occur in an area C′, causing damage to the common electrode 730, hole transporting layer HTL, and the second spacer SPC2. Since the interior angle of the second spacer SPC2 is an obtuse angle, the hole transporting layer HTL and the electron transporting layer ETL may be disconnected for each pixel in area D. Accordingly, even in case that damage occurs in the area C′, the filler 310 may not penetrate into the emission area of the pixel due to the disconnection in an area D. Therefore, even in case that damage occurs to the second spacer SPC2, a darkening of the pixel may be prevented. In area C′, the second spacer SPC2 and the filler 310 may be in contact with each other through the groove of the second spacer SPC2.

Since the sagging of the mask described above may occur at the edge of the display substrate 110, damage to the spacer may occur at the edge of the display substrate 110 described above. According to an embodiment, since the first spacer SPC1 is disposed at the center of the display substrate 110 where sagging of the mask does not occur, while the second spacer SPC2 is disposed at the edge of the display substrate 110 where sagging of the mask may occur, darkening of the pixel may be prevented even in case that the second spacer SPC2 disposed at the edge of the display panel is damaged.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first substrate;
a transistor on the first substrate;
a pixel electrode disposed on the transistor and connected to the transistor;
a pixel defining layer on the pixel electrode;
a spacer on the pixel defining layer; and
a second substrate on the spacer, wherein
the spacer comprises a first spacer disposed at a center of the first substrate and a second spacer disposed at an edge of the first substrate in a plan view, and
the second spacer has a width that gradually increases in a direction from the first substrate toward the second substrate.

2. The display device of claim 1, wherein the first spacer has a width that gradually decreases in the direction.

3. The display device of claim 1, wherein an interior angle of the second spacer is an obtuse angle.

4. The display device of claim 1, wherein an interior angle of the first spacer is an acute angle.

5. The display device of claim 1, further comprising:
a filler between the first substrate and the second substrate.

6. The display device of claim 5, wherein the second spacer has a groove.

7. The display device of claim 6, wherein the second spacer and the filler are in contact with each other through the groove of the second spacer.

8. The display device of claim 5, further comprising:
a sealant disposed between the edge of the first substrate and an edge of the second substrate and surround the filler and the spacer.

9. The display device of claim 1, wherein the spacer is formed integrally with the pixel defining layer.

10. The display device of claim 9, wherein each of the first spacer and the second spacer is formed integrally with the pixel defining layer.

11. The display device of claim 5, wherein the filler is formed of a silicon-based material.

12. A display device comprising:
a first substrate;
a transistor on the first substrate;
a pixel electrode disposed on the transistor and connected to the transistor;
a pixel defining layer on the pixel electrode; and
a first spacer disposed on the pixel defining layer at an edge of the first substrate in a plan view,
wherein the first spacer has a width that gradually increases in a direction from the first substrate toward a second substrate.

13. The display device of claim 12, wherein an interior angle of the first spacer is an obtuse angle.

14. The display device of claim 13, further comprising:
a second spacer disposed on the pixel defining layer at a center of the first substrate in a plan view,
wherein the second spacer has a width that gradually decreases in the direction.

15. The display device of claim 14, wherein an interior angle of the second spacer is an acute angle.

16. The display device of claim 12, further comprising:
a filler between the first substrate and the second substrate.

17. The display device of claim 16, wherein the first spacer has a groove.

18. The display device of claim 17, wherein the first spacer and the filler are in contact with each other through the groove of the first spacer.

19. The display device of claim 16, further comprising:
a sealant disposed between the edge of the first substrate and an edge of the second substrate and surround the filler, the first spacer, and the second spacer.

20. The display device of claim 12, wherein each of the first spacer and the second spacer is formed integrally with the pixel defining layer.
